(19) United States
(12) Patent Application Publication
(10) Pub. No.: US 2025/0098218 A1
(43) Pub. Date: Mar. 20, 2025

(54) THIN FILM TRANSISTOR AND DISPLAY DEVICE INCLUDING THE SAME

(71) Applicant: ELECTRONICS AND TELECOMMUNICATIONS RESEARCH INSTITUTE, Daejeon (KR)

(72) Inventors: Jae-Eun PI, Daejeon (KR); Seung Youl KANG, Daejeon (KR); Yong Hae KIM, Daejeon (KR); Joo Yeon KIM, Daejeon (KR); Hee-ok KIM, Daejeon (KR); Jaehyun MOON, Daejeon (KR); Jong-Heon YANG, Daejeon (KR); Himchan OH, Daejeon (KR); Seong-Mok CHO, Daejeon (KR); Ji Hun CHOI, Daejeon (KR); Chi-Sun HWANG, Daejeon (KR)

(73) Assignee: ELECTRONICS AND TELECOMMUNICATIONS RESEARCH INSTITUTE, Daejeon (KR)

(21) Appl. No.: 18/762,381

(22) Filed: Jul. 2, 2024

(30) Foreign Application Priority Data
Sep. 19, 2023 (KR) 10-2023-0125060
Feb. 2, 2024 (KR) 10-2024-0016817

(51) Int. Cl. H01L 29/417; G02F 1/1362; G02F 1/1368; H01L 27/12; H01L 29/786

(52) U.S. Cl. CPC H10D 30/6729; G02F 1/136286; G02F 1/1368; H10D 30/6757; H10D 86/441; H10D 86/60

(57) ABSTRACT

A thin film transistor includes a first gate electrode on a substrate, a gate insulating film on the first gate electrode, a first active layer on the gate insulating film, a drain electrode on one side of the first active layer, a sidewall spacer on a side wall of the drain electrode, and a first source electrode provided on the other side of the first active layer and a sidewall of the sidewall spacer.

### CROSS-REFERENCE TO RELATED APPLICATIONS

This U.S. non-provisional patent application claims priority under 35U.S.C. § 119 of Korean Patent Application Nos. 10-2023-0125060, filed on Sep. 19, 2023, and 10-2024-0016817, filed on Feb. 2, 2024, the entire contents of which are hereby incorporated by reference.

### BACKGROUND

The present disclosure herein relates to a display device, and more particularly, to a thin film transistor and a display device including the same.

In general, a thin film transistor constituting a display pixel and a circuit may be constituted by three terminals, i.e., a gate, a source, drain and may be driven in a manner in which electronic channels between the source-drain electrodes are turned on and/or turned off by gate electric fields with a semiconductor active layer between gate insulating films. In the thin film transistor, due to a limitation of the large-area display exposure process set up for mass production, a channel length is on a level of several micrometers, and thus, current driving ability is significantly lower than that of CMOS Si backplane FET, and an area of the thin film transistor may be as large as the channel length to cause a limitation in implementation of ultra-high-resolution displays for the metaverse, which has recently emerged.

### SUMMARY

The present disclosure provides a thin film transistor that is capable of reducing or minimizing a channel length and a display device including the same.

An embodiment of the inventive concept includes a thin film transistor. The thin film transistor includes: a first gate electrode on a substrate; a gate insulating film on the first gate electrode; a first active layer on the gate insulating film; a drain electrode on one side of the first active layer; a sidewall spacer on a sidewall of the drain electrode; and a first source electrode provided on the other side of the first active layer and a sidewall of the sidewall spacer.

In an embodiment, the first active layer may have a first channel length corresponding to a bottom thickness of the sidewall spacer.

In an embodiment, the thin film transistor may further include a blocking insulating film on the drain electrode.

In an embodiment, the first source electrode may be provided on the blocking insulating film.

In an embodiment, the thin film transistor may further include an upper electrode between the blocking insulating film and the first source electrode.

In an embodiment, the thin film transistor may further include a second active layer between the drain electrode and the blocking insulating film.

In an embodiment, the thin film transistor may further include a second source electrode between the second active layer and the blocking insulating film.

In an embodiment, the thin film transistor may further include a second gate electrode on the sidewall spacer.

In an embodiment, the second gate electrode may be connected to the first source electrode.

In an embodiment, the second active layer may have a second channel length corresponding to a thickness of the second active layer.

In an embodiment of the inventive concept, a thin film transistor includes: a first gate electrode on a substrate; a gate insulating film on the first gate electrode; a first active layer on the gate insulating film; a drain electrode on one side of the first active layer; a first source electrode on another side of the first active layer; a second active layer on the drain electrode; a second source electrode on the second active layer: a sidewall spacer on sidewalls of the drain electrode, the second active layer, and the second source electrode; and a second gate electrode on a sidewall of the sidewall spacer.

In an embodiment, the second gate electrode may be connected to the first source electrode.

In an embodiment, the thin film transistor may further include a blocking insulating film provided on the second source electrode.

In an embodiment, the second gate electrode may extend to the blocking insulating film.

In an embodiment, the first active layer may have a first channel length corresponding to a bottom thickness of the sidewall spacer, and the second active layer may have a second channel length corresponding to a thickness of the second active layer.

In an embodiment of the inventive concept, a display device includes: a scan line extending in a first direction; a data line extending in a second direction crossing the first direction; and a thin film transistor provided at a point at which the data line and the scan line cross each other. In an embodiment, the thin film transistor may include: a first gate electrode on a lower substrate; a gate insulating film on the first gate electrode; a first active layer on the gate insulating film; a drain electrode on one side of the first active layer; a sidewall spacer on a sidewall of the drain electrode; and a first source electrode provided on the other side of the first active layer and a sidewall of the sidewall spacer.

In an embodiment, the active layer may overlap the data line.

In an embodiment, the first gate electrode may extend in the first direction, and the first source electrode may extend in the second direction.

In an embodiment, the first active layer may have the same width as each of the first gate electrode and the scan line.

In an embodiment, the scan line may be wider or thicker than the data line.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view illustrating an example of a display device according to the inventive concept;

FIG. 2 is a cross-sectional view taken along line I-I′ of FIG. 1;

FIG. 3 is a plan view illustrating an example of the display device according to the inventive concept;

FIG. 4 is a cross-sectional view taken along line II-II′ of FIG. 3;

FIG. 5 is a plan view illustrating an example of a thin film transistor of FIG. 1;

FIG. 6 is a cross-sectional view taken along line III-III′ of FIG. 5.

FIG. 7 is a plan view illustrating an example of thin film transistors of FIG. 1;

FIG. 8 is a cross-sectional view taken along line IV-IV′ of FIG. 7;

FIG. 9 is a plan view illustrating an example of thin film transistors of FIG. 1;

FIG. 10 is a cross-sectional view taken along line V-V′ of FIG. 9;

FIG. 11 is a cross-sectional view illustrating an example of the thin film transistor of FIG. 2; and

FIG. 12 is a cross-sectional view illustrating an example of the thin film transistor of FIG. 2.

### DETAILED DESCRIPTION

Preferred embodiments of the present invention will be described below in detail with reference to the accompanying drawings. Advantages and features of the present invention, and implementation methods thereof will be clarified through description of the following embodiments with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those having ordinary skill in the art, and the present invention is only defined by the scope of the claims. Like reference numerals refer to like elements throughout.

In the following description, the technical terms are used only for explaining a specific exemplary embodiment while not limiting the present invention. In this specification, the terms of a singular form may comprise plural forms unless specifically mentioned. The meaning of “comprises” and/or “comprising” specifies a component, an operation and/or an element wherein other components, operations and/or elements are not excluded. Since the reference numbers are provided according to the exemplary embodiments of the inventive concept, the order of the reference numerals given in the description is not limited thereto.

Additionally, the embodiments in the detailed description will be described with sectional and other views as ideal exemplary views of the present embodiments. In the figures, the dimensions of layers and regions may be exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes.

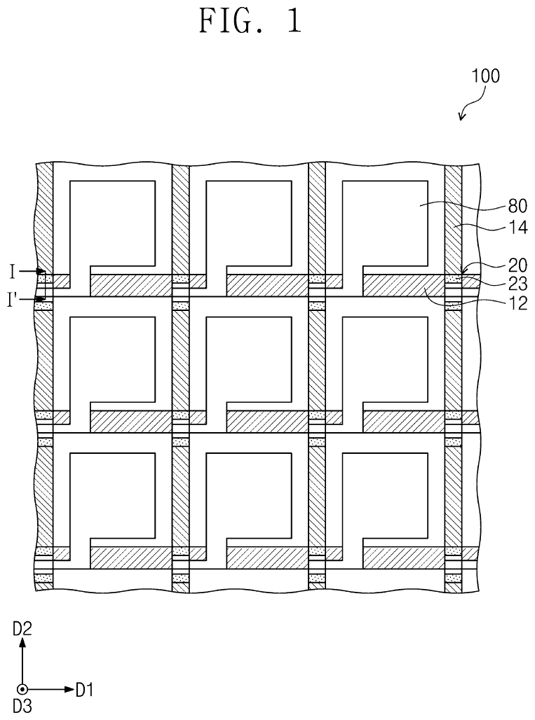

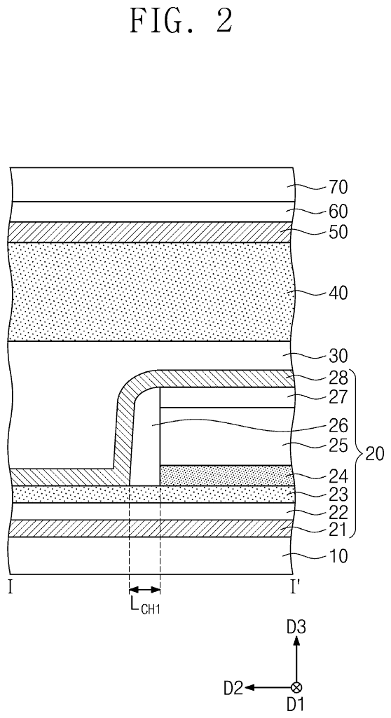

FIG. 1 is a plan view illustrating an example of a display device 100 according to the inventive concept. FIG. 2 is a cross-sectional view taken along line I-I′ of FIG. 1.

Referring to FIGS. 1 and 2, the display device 100 of the inventive concept may include a liquid crystal display device. Alternatively, the display device 100 of the inventive concept may include an organic light emitting display device, but the inventive concept is not limited thereto. According to an embodiment, the display device 100 may include a lower substrate 10, a scan line 12, a data line 14, a pixel electrode 80, a thin film transistor 20, a protective film 30, a liquid crystal layer 40, a common electrode 50, a color filter layer 60, and an upper substrate 70.

The lower substrate 10 may be a transparent substrate. For example, the lower substrate 10 may include a glass substrate or a plastic substrate.

The scan line 12 may be provided on the lower substrate 10. The scan line 12 may extend in a first direction D1. For example, the scan line 12 may include a metal such as gold (Au), silver (Ag), copper (Cu), aluminum (Al), tungsten (W), molybdenum (Mo), nickel (Ni), titanium (Ti), or tantalum (Ta). Alternatively, the scan line 12 may include indium tin oxide (ITO), but the inventive concept is not limited thereto.

The data line 14 may be provided on the scan line 12. The data line 14 may extend in a second direction D2. The second direction D2 may cross the first direction D1. The data line 14 may have the same material as the scan line 12. For example, the data line 14 may include a metal such as gold (Au), silver (Ag), copper (Cu), aluminum (Al), tungsten (W), molybdenum (Mo), nickel (Ni), titanium (Ti), or tantalum (Ta). Alternatively, the data line 14 may include indium tin oxide (ITO), but the invention is not limited thereto.

The thin film transistor 20 may be provided at a point at which the scan line 12 and the data line 14 cross each other in a plan view. The thin film transistor 20 may overlap the data line 14. Although not shown, the thin film transistor 20 may be provided between the data line 14 and the scan line 12 in a point of view. The thin film transistor 20 may drive the pixel electrode 80. That is, the thin film transistor 20 may control a data voltage or data signal provided to the pixel electrode 80. The thin film transistor 20 may include a bottom gate thin film transistor (TFT) or a back channel etched thin film transistor (BCE TFT).

Referring to FIG. 2, the thin film transistor 20 may include a first gate electrode 21, a gate insulating film 22, a first active layer 23, a drain electrode 24, a blocking insulating film 25, a sidewall spacer 26, an upper electrode 27, and a first source electrode 28.

The first gate electrode 21 may be provided on the substrate 10. The first gate electrode 21 may be the scan line 12 of FIG. 1 or may be connected to the scan line 12. That is, the first gate electrode 21 may extend in the first direction D1. The first gate electrode 21 may include a metal such as gold (Au), silver (Ag), copper (Cu), aluminum (Al), tungsten (W), molybdenum (Mo), nickel (Ni), titanium (Ti), or tantalum (Ta). Alternatively, the first gate electrode 21 may include indium tin oxide (ITO), but the inventive concept is not limited thereto.

The gate insulating film 22 may be provided on the first gate electrode 21. For example, the gate insulating film 22 may include silicon oxide. Alternatively, the gate insulating film 22 may include silicon nitride, but the inventive concept is not limited thereto.

The first active layer 23 may be provided on the gate insulating film 22. The first active layer 23 may overlap the first gate electrode 21 and the data line 14. For example, the first active layer 23 may include polysilicon or amorphous silicon. Alternatively, the first active layer 23 may include crystalline silicon, but the invention is not limited thereto.

The drain electrode 24 may be provided on one side of the first active layer 23. Although not shown, the drain electrode 24 may be connected to the pixel electrode 80. For example, the drain electrode 24 may include indium tin oxide (ITO). Alternatively, the drain electrode 24 may include a metal of gold (Au), silver (Ag), copper (Cu), aluminum (Al), tungsten (W), molybdenum (Mo), nickel (Ni), titanium (Ti), or tantalum (Ta), but the inventive concept is not limited thereto.

A blocking insulating film 25 may be provided on the drain electrode 24. The blocking insulating film 25 may include a dielectric of silicon oxide or silicon nitride.

The upper electrode 27 may be provided on the blocking insulating film 25. The upper electrode 27 may include a metal such as gold (Au), silver (Ag), copper (Cu), aluminum (Al), tungsten (W), molybdenum (Mo), nickel (Ni), titanium (Ti), or tantalum (Ta), but the inventive concept is not limited thereto.

The sidewall spacer 26 may be provided on one sidewall of the drain electrode 24, the blocking insulating film 25, and the upper electrode 27. The sidewall spacer 26 may include silicon oxide or silicon nitride formed by a plasma enhanced chemical vapor deposition (PECVD) method. The sidewall spacer 26 may be formed by a self-aligning method.

The first source electrode 28 may be provided on the other side of the first active layer 23. The first source electrode 28 may be provided on the sidewall spacer 26 and the upper electrode 27. The first source electrode 28 may be the data line 14 of FIG. 1. That is, the first source electrode 28 may extend in the second direction D2. The first source electrode 28 may be provided on the blocking insulating film 25 and the upper electrode 27. Alternatively, the first source electrode 28 may be connected to the data line 14. For example, the first source electrode 28 may include a metal such as gold (Au), silver (Ag), copper (Cu), aluminum (Al), tungsten (W), molybdenum (Mo), nickel (Ni), titanium (Ti), or tantalum (Ta). Alternatively, the first source electrode 28 may include indium tin oxide (ITO), but the inventive concept is not limited thereto.

When the gate voltage or scan signal is provided to the first gate electrode 21, a first channel may be provided in the first active layer 23 between the first source electrode 28 and the drain electrode 24. The first active layer 23 may have a first channel length LCH1. For example, the first channel length LCH1 may be about 0.1 μm. The first channel may have a width of about 15 μm. According to an embodiment, the first channel length LCH1 may correspond to a bottom thickness of the sidewall spacer 26.

Thus, the thin film transistor 20 of the inventive concept may use the first source electrode 28 and the drain electrode 24 at both sides of the sidewall spacer 26 on the first gate electrode 21 and the first active layer 23 to reduce or minimize the first channel length LCH1 so as to correspond to the bottom thickness of the sidewall spacer 26.

When a first channel is provided in the first active layer 23, the data voltage or data signal may be provided from the first source electrode 28 to the drain electrode 24 through the first channel. The data voltage or data signal may induce electric fields between the pixel electrode 80 and the common electrode 50 to change optical characteristics or polarization direction of the liquid crystal layer 40.

The protective film 30 may be provided on the first source electrode 28. The protective film 30 may have a flat top surface. The protective film 30 may include silicon oxide.

The pixel electrode 80 may be provided to a pixel defined by the scan line 12 and the data line 14. Although not shown, the pixel electrode 80 may be provided on the protective film 30. The pixel electrode 80 may be connected to one side of the drain electrode 24 of the thin film transistor 20 through a contact electrode passing through the protective film 30.

The liquid crystal layer 40 may be provided on the protective film 30 and the pixel electrode 80. The liquid crystal layer 40 may change the optical characteristics or polarization direction in response to the electric fields induced between the pixel electrode 80 and the common electrode 50. For example, the liquid crystal layer 40 may include a smectic liquid crystal, a nematic liquid crystal, or a cholesteric liquid crystal.

The common electrode 50 may be provided on the liquid crystal layer 40. The common electrode 50 may include indium tin oxide (ITO). The common electrode 50 may be grounded.

The color filter layer 60 may be provided on the common electrode 50. The color filter layer 60 may include polymers or pigments with red, green, and blue colors.

The upper substrate 70 may be provided on the color filter layer 60. The upper substrate 70 may be transparent. The upper substrate 70 may include a glass substrate or a plastic substrate.

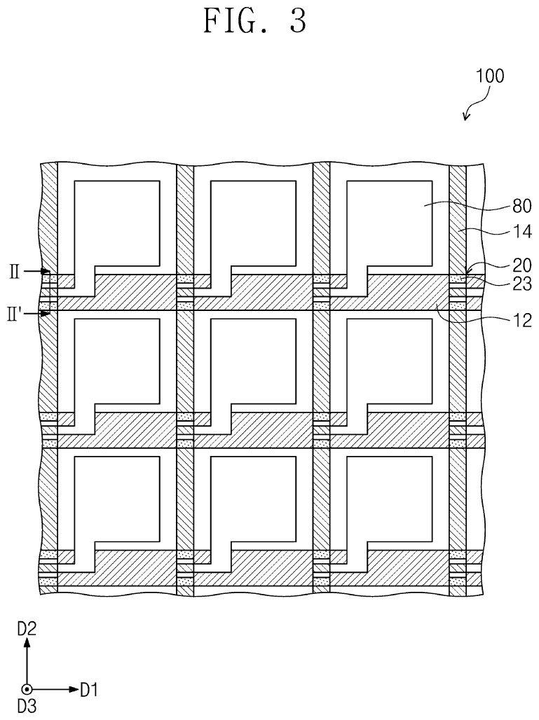

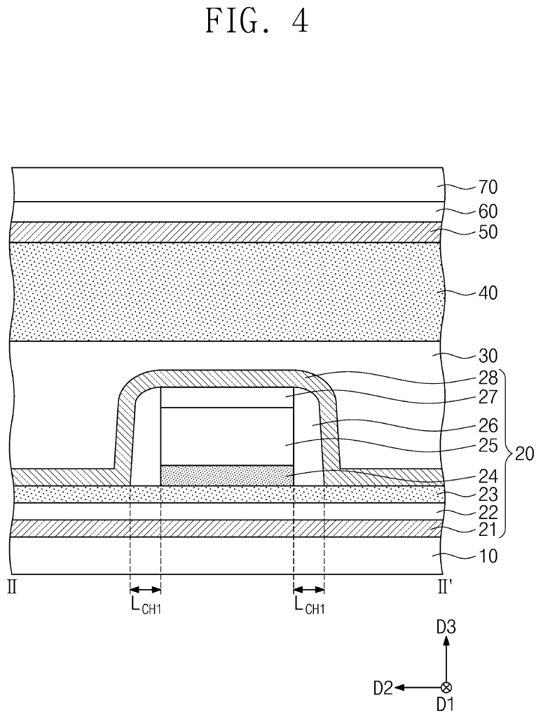

FIG. 3 is a plan view illustrating an example of the display device 100 according to the inventive concept. FIG. 4 is a cross-sectional view taken along line II-II′ of FIG. 3.

Referring to FIGS. 3 and 4, the sidewall spacers 26 of the thin film transistor 20 of the inventive concept may be provided on both sidewalls of the drain electrode 24, the blocking insulating film 25, and the upper electrode 27, respectively. That is, each of the thin film transistors 20 may have a plurality of first channels. A width of the first active layer 23 of the thin film transistor 20 may be the same as that of each of the scan line 12 and the first gate electrode 21. The scan line 12 may be wider or thicker than data line 14.

The lower substrate 10, the first gate electrode 21, the gate insulating film 22, the first active layer 23, the drain electrode 24, the blocking insulating film 25, the upper electrode 27, the first source electrode 28, the protective film 30, the liquid crystal layer 40, the common electrode 50, the color filter layer 60, the upper substrate 70, and the pixel electrode 80 may be configured to be the same as those in FIGS. 1 and 2.

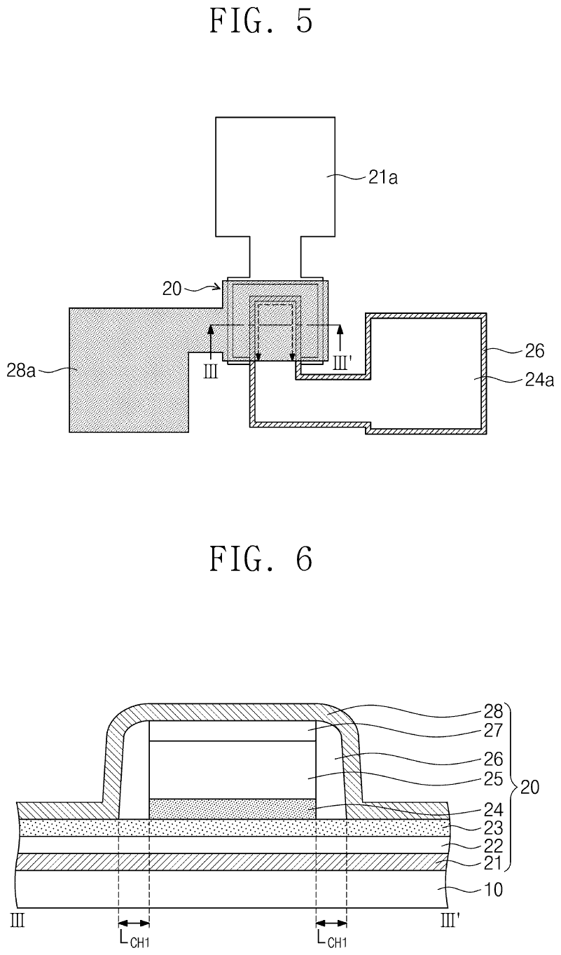

FIG. 5 is a plan view illustrating an example of the thin film transistor of FIG. 1. FIG. 6 is a cross-sectional view taken along line III-III′ of FIG. 5.

Referring to FIGS. 5 and 6, the first gate electrode 21, drain electrode 24, and first source electrode 28 of the thin film transistor 20 may be connected to a gate pad 21a, a drain pad 24a, and a source pad 28a, respectively.

The lower substrate 10, the first gate electrode 21, the gate insulating film 22, the first active layer 23, the drain electrode 24, the blocking insulating film 25, the upper electrode 27, and the first source electrode 28 may be configured to be the same as those in FIG. 2.

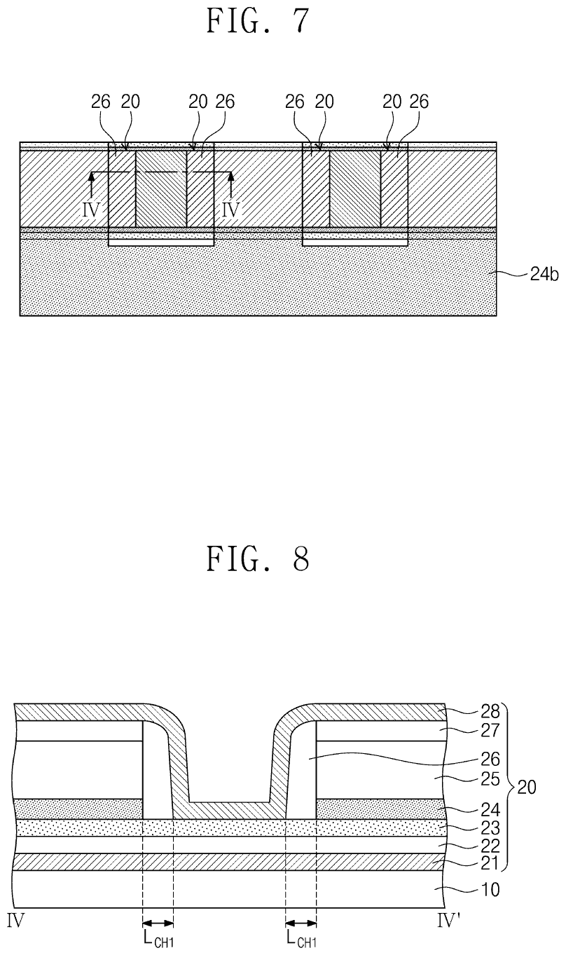

FIG. 7 is a plan view illustrating an example of the thin film transistors of FIG. 1. FIG. 8 is a cross-sectional view taken along line IV-IV′ of FIG. 7.

Referring to FIGS. 7 and 8, the drain electrodes 24 of the thin film transistors 20 may be connected in parallel by a connection line 24b. The first source electrode 28 may be in contact with the first active layer 23 between the sidewall spacers 26.

The lower substrate 10, the first gate electrode 21, the gate insulating film 22, the first active layer 23, the drain electrode 24, the blocking insulating film 25, the upper electrode 27, and the first source electrode 28 may be configured to be the same as those in FIG. 2.

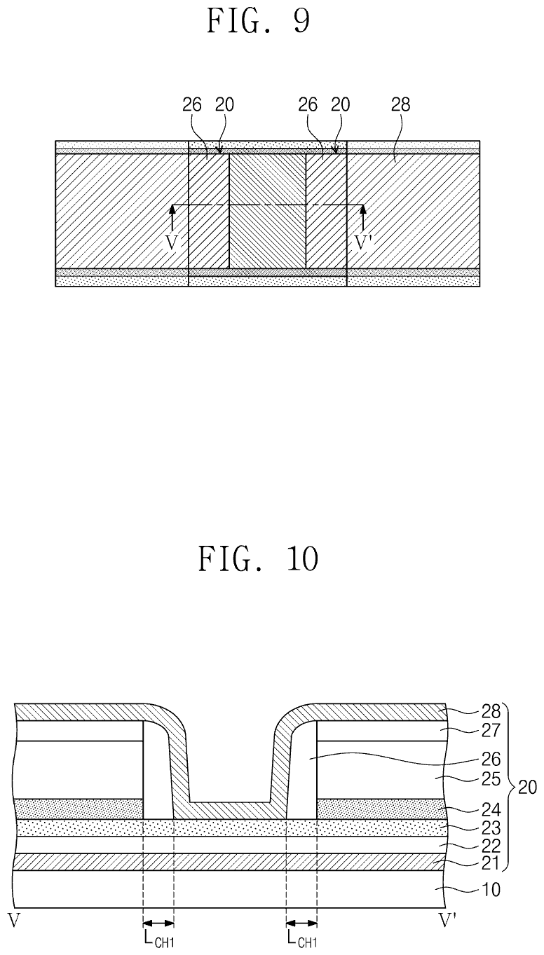

FIG. 9 is a plan view illustrating an example of the thin film transistors of FIG. 1. FIG. 10 is a cross-sectional view taken along line V-V′ of FIG. 9; FIG. 10 may correspond to FIG. 8.

Referring to FIGS. 9 and 10, the thin film transistors 20 may be connected in series. At least one of drain electrodes 24 may be connected to or function as a source electrode or gate electrode of another thin film transistor, but the inventive concept is not limited thereto.

The lower substrate 10, the first gate electrode 21, the gate insulating film 22, the first active layer 23, the drain electrode 24, the blocking insulating film 25, the upper electrode 27, and the first source electrode 28 may be configured to be the same as those in FIG. 2.

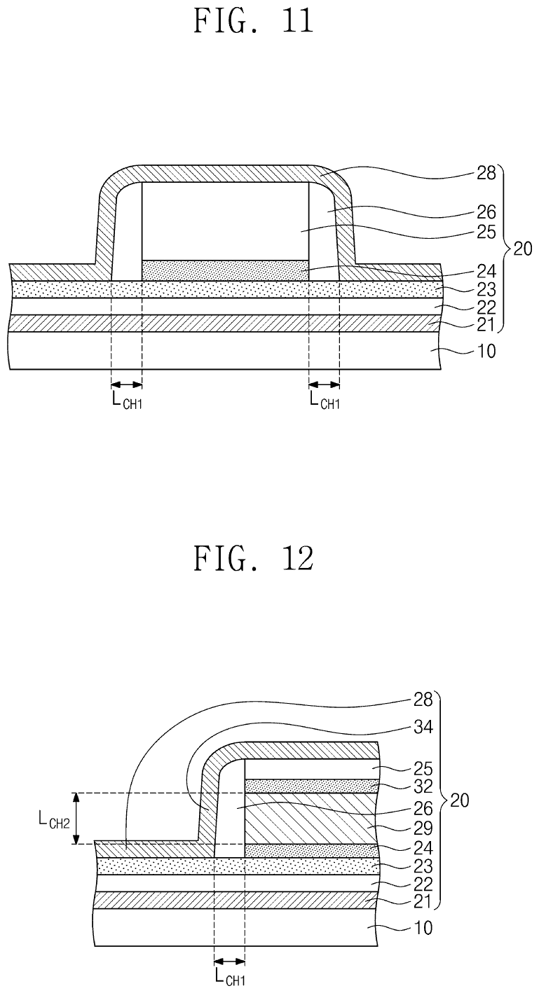

FIG. 11 is a cross-sectional view illustrating an example of the thin film transistor of FIG. 2.

Referring to FIG. 11, the first source electrode 28 of the thin film transistor 20 may be in contact with the blocking insulating film 25 without the upper electrode 27 of FIG. 2. A top surface of the blocking insulating film 25 may be coplanar with the top surface of the sidewall spacer 26.

The lower substrate 10, the first gate electrode 21, the gate insulating film 22, the first active layer 23, the drain electrode 24, the blocking insulating film 25, and the first source electrode 28 may be configured to be the same as those in FIG. 2.

FIG. 12 is a cross-sectional view illustrating an example of an additional embodiment that includes layers not illustrated in the thin film transistor of FIG. 2.

Referring to FIG. 12, the additional embodiment of the thin film transistor 20 may further include a second active layer 29, a second source electrode 32, and a second gate electrode 34.

The second active layer 29 may be provided between the drain electrode 24 and the blocking insulating film 25. The second active layer 29 may be thinner in the D3 direction than the sidewall spacer 26. For example, the second active layer 29 may include amorphous silicon, polysilicon, or crystalline silicon, but the inventive concept is not limited thereto.

The second source electrode 32 may be provided between the second active layer 29 and the blocking insulating film 25. The blocking insulating film 25 may be provided between the second source electrode 32 and the second gate electrode 34. In addition, the blocking insulating film 25 may be provided between the first source electrode 28 and the second source electrode 32. That is, the second source electrode 32 may be insulated from the first source electrode 28 and the second gate electrode 34 by the blocking insulating film 25.

The second gate electrode 34 may be provided on a sidewall of the sidewall spacer 26. The second gate electrode 34 may be connected to the first source electrode 28. The second gate electrode 34 may include the same material as the first source electrode 28. When the data voltage or data signal is provided to the first source electrode 28 and the second gate electrode 34, the second gate electrode 34 may induce a second channel in the second active layer 29.

The second active layer 29 may have a second channel length LCH2. The second channel length LCH2 may correspond to a thickness of the second active layer 29.

As a result, the thin film transistor 20 of the inventive concept may use the first gate electrode 21, the drain electrode 24, the first source electrode 28, the second source electrode 32, and the second gate electrode 34 to reduce or minimize the first channel length LCH1 and the second channel length LCH2.

The lower substrate 10, the first gate electrode 21, the gate insulating film 22, the first active layer 23, and the drain electrode 24 may be configured to be the same as those in FIG. 2.

As described above, in the thin film transistor according to the inventive concept, the channel length may be reduced or minimized to correspond to the bottom thickness of the sidewall spacer by using the source electrode and drain electrode at both sides of the sidewall spacer on the gate electrode and active layer.

Although the embodiment of the inventive concept is described with reference to the accompanying drawings, those with ordinary skill in the technical field of the inventive concept pertains will be understood that the present disclosure can be carried out in other specific forms without changing the technical idea or essential features. Thus, the above-disclosed embodiments are to be considered illustrative and not restrictive.

What is claimed is:

1. A thin film transistor comprising:
a first gate electrode on a substrate;
a gate insulating film on the first gate electrode;
a first active layer on the gate insulating film;
a drain electrode on one side of the first active layer;
a sidewall spacer on a sidewall of the drain electrode; and
a first source electrode provided on another side of the first active layer and a sidewall of the sidewall spacer.

2. The thin film transistor of claim 1, wherein the first active layer has a first channel length corresponding to a bottom thickness of the sidewall spacer.

3. The thin film transistor of claim 1, further comprising a blocking insulating film on the drain electrode.

4. The thin film transistor of claim 3, wherein the first source electrode is provided on the blocking insulating film.

5. The thin film transistor of claim 3, further comprising an upper electrode between the blocking insulating film and the first source electrode.

6. The thin film transistor of claim 3, further comprising a second active layer between the drain electrode and the blocking insulating film.

7. The thin film transistor of claim 6, further comprising a second source electrode between the second active layer and the blocking insulating film.

8. The thin film transistor of claim 7, further comprising a second gate electrode on the sidewall spacer.

9. The thin film transistor of claim 8, wherein the second gate electrode is connected to the first source electrode.

10. The thin film transistor of claim 6, wherein the second active layer has a second channel length corresponding to a thickness of the second active layer.

11. A thin film transistor comprising:
a first gate electrode on a substrate;
a gate insulating film on the first gate electrode;
a first active layer on the gate insulating film;
a drain electrode on one side of the first active layer;
a first source electrode on another side of the first active layer;
a second active layer on the drain electrode;
a second source electrode on the second active layer:
a sidewall spacer on sidewalls of the drain electrode, the second active layer, and the second source electrode; and
a second gate electrode on a sidewall of the sidewall spacer.

12. The thin film transistor of claim 11, wherein the second gate electrode is connected to the first source electrode.

13. The thin film transistor of claim 11, further comprising a blocking insulating film provided on the second source electrode.

14. The thin film transistor of claim 11, wherein the second gate electrode is provided on the blocking insulating film.

15. The thin film transistor of claim 11, wherein the first active layer has a first channel length corresponding to a bottom thickness of the sidewall spacer, and
the second active layer has a second channel length corresponding to a thickness of the second active layer.

16. A display device comprising:
a scan line extending in a first direction;
a data line extending in a second direction crossing the first direction; and
a thin film transistor provided at a point at which the data line and the scan line cross each other,
wherein the thin film transistor comprises:
a first gate electrode on a lower substrate;
a gate insulating film on the first gate electrode;
a first active layer on the gate insulating film;
a drain electrode on one side of the first active layer;
a sidewall spacer on a sidewall of the drain electrode; and
a first source electrode provided on another side of the first active layer and a sidewall of the sidewall spacer.

17. The display device of claim 16, wherein the first active layer overlaps the data line.

18. The display device of claim 16, wherein the first gate electrode extends in the first direction, and
the first source electrode extends in the second direction.

19. The display device of claim 16, wherein the first active layer has a same width as each of the first gate electrode and the scan line.

20. The display device of claim 16, wherein the scan line is wider or thicker than the data line.
